(19) United States
(12) Patent Application Publication
(10) Pub. No.: US 2010/0279437 A1
(43) Pub. Date: Nov. 4, 2010

(54) CONTROLLING EDGE EMISSION IN PACKAGE-FREE LED DIE

(75) Inventors: James G. Neff, Felton, CA (US); Serge J. Bierhuizen, Santa Rosa, CA (US)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/433,972

(22) Filed: May 1, 2009

(51) Int. Cl. H01L 21/66

(52) U.S. Cl. 438/14; 257/E21.529; 257/E21.532; 438/29

(57) ABSTRACT

Light emitting diode (LED) structures are fabricated in wafer scale by mounting singulated LED dies on a carrier wafer or a stretch film, separating the LED dies to create spaces between the LED dies, applying a reflective coating over the LED dies and in the spaces between the LED dies, and separating or breaking the reflective coating in the spaces between the LED dies such that some reflective coating remains on the lateral sides of the LED die. Portions of the reflective coating on the lateral sides of the LED dies may help to control edge emission.

### CROSS REFERENCE TO RELATED APPLICATION

This application is related to U.S. patent application Ser. No. 12/178,902, entitled “Semiconductor Light Emitting Device Including a Window Layer and a Light-Directing Structure,” filed on Jul. 24, 2008, which is incorporated herein by reference.

### FIELD OF INVENTION

The present disclosure relates to light emitting diodes (LEDs) and, in particular, to package-free LED dies.

### DESCRIPTION OF RELATED ART

Semiconductor LEDs are among the most efficient light sources currently available. Materials systems currently of interest in the manufacture of high-brightness light emitting devices capable of operation across the visible spectrum include Group III-V semiconductors; for example, binary, ternary, and quaternary alloys of gallium, aluminum, indium, nitrogen, phosphorus, and arsenic. III-V devices emit light across the visible spectrum. GaAs- and GaP-based devices are often used to emit light at longer wavelengths such as yellow through red, while III-nitride devices are often used to emit light at shorter wavelengths such as near-UV through green.

Gallium nitride LEDs typically use a transparent sapphire growth substrate due to the crystal structure of sapphire being similar to the crystal structure of gallium nitride.

Some GaN LEDs are formed as flip chips, with both electrodes on the same surface, where the LED electrodes are bonded to electrodes on a submount without using wire bonds. In such a case, light is transmitted through the transparent sapphire substrate, and the LED layers oppose the submount. A submount provides an interface between the LED and an external power supply. Electrodes on the submount bonded to the LED electrodes may extend beyond the LED or extend to the opposite side of the submount for wire bonding or surface mounting to a circuit board.

### SUMMARY

In some embodiments of the present disclosure, light emitting diode (LED) dies on a device wafer are separated to create spaces between the LED dies, and a reflective coating is applied over the LED dies and in the spaces between the LED dies. When the LED dies are again separated, portions of the reflective coating remain on the lateral sides of the LED dies. The reflective coating on the lateral sides of the LED dies may control edge emission, improve color-over-angle uniformity, and improve brightness. The reflective coating may be a polymer or a resin with reflective particles, or a thin metal film.

### BRIEF DESCRIPTION OF THE DRAWINGS

FIG. 1 is a flowchart of a method to fabricate light emitting diode (LED) structures in wafer scale using a reflective coating to control edge emission from LED dies;

FIGS. 2 to 13 illustrate cross-sectional views of the processes in the method of FIG. 1 when the reflective coating is a polymer or a resin with reflective particles; and

FIGS. 14 to 17 illustrate cross-sectional views of the processes in the method of FIG. 1 when the reflective coating is a thin metal film, all arranged in accordance with embodiments of the invention.

Use of the same reference numbers in different figures indicates similar or identical elements.

### DETAILED DESCRIPTION

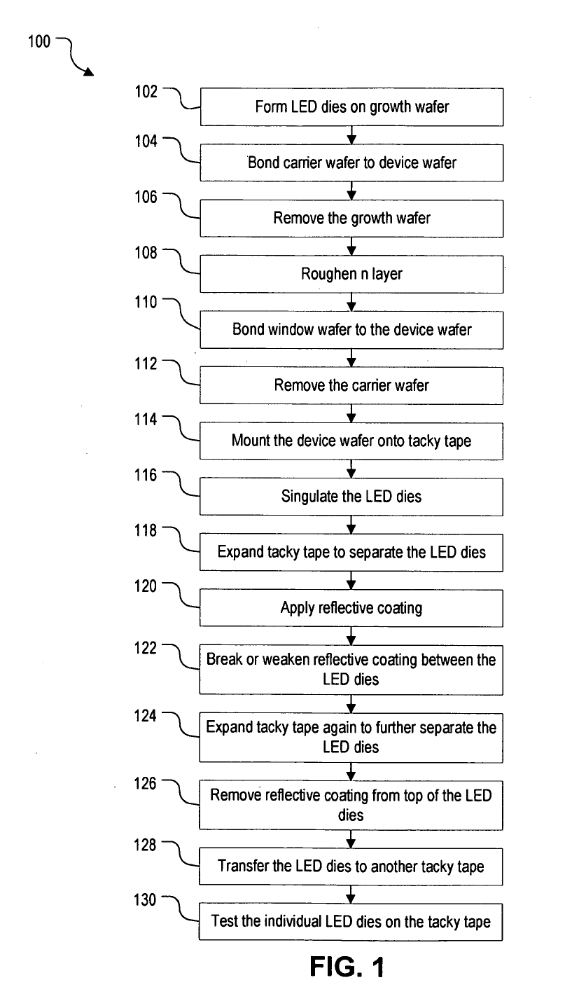

FIG. 1 is a flowchart of a method 100 to fabricate light emitting diode (LED) structures in wafer scale using a reflective coating to control edge emission from LED dies in some embodiments of the present disclosure. Method 100 includes processes 102 to 130.

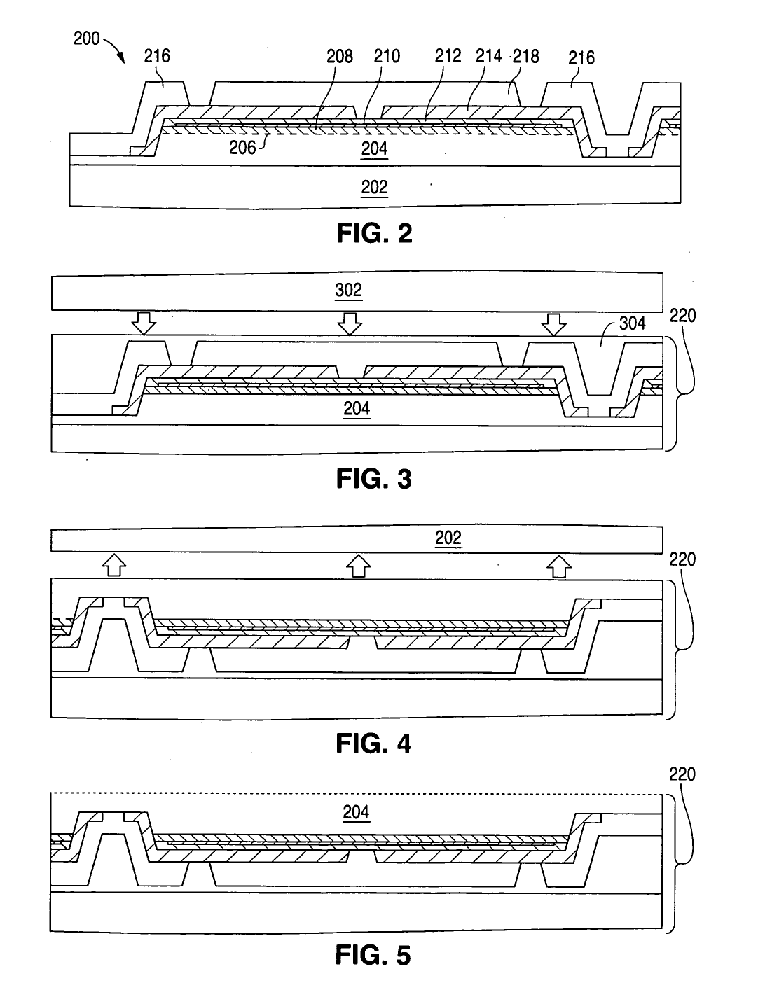

In process 102, example LED dies 200 are formed on a growth wafer. For simplicity, a single LED die 200 is illustrated in FIG. 2. LED die 200 includes a growth wafer 202, an n-type layer 204 epitaxially grown over the growth wafer, a light-emitting layer 206 (also common referred to as an “active layer”) epitaxially grown over the n-type layer, a p-type layer 208 epitaxially grown over the light-emitting layer, a conductive reflective layer 210 formed over the p-type layer, and a guard metal layer 212 formed over the conductive reflective layer. A dielectric 214 is formed over the structures. Openings are formed in the various layers to provide access to n-type layer 204 and conductive reflective layer 210 for p-type layer 208. One or more n-type bond pads 216 are formed to electrically contact n-type layer 204, and one or more p-type bond pads 218 are formed to electrically contact conductive reflective layer 210. Instead of LED dies 200, method 100 may be applied to other types of LED dies or other light emitting devices that have edge emission. Process 102 is followed by process 104.

In process 104, a carrier wafer 302 is temporarily bonded to device wafer 220. Hereafter “device wafer 220” refers to the wafer scale structure including LED dies 200 in a process. A removable adhesive 304 is first applied over the top of device wafer 220 and carrier wafer 302 is then bonded to the top of the device wafer as shown in FIG. 3. Removable adhesive 302 may be applied in a spin-on process. Process 104 is followed by process 106.

In process 106, device wafer 220 is flipped over and growth wafer 202 is removed as shown in FIG. 4. Growth wafer 202 may be removed by a laser lift-off process. Process 106 is followed by process 108.

In process 108, n-type layer 204 is roughened to improve light extraction as shown in FIG. 5. N-type layer 204 may be roughened in a physical process (e.g., grinding or lapping) or a chemical process (e.g., etching). Process 108 is followed by process 110.

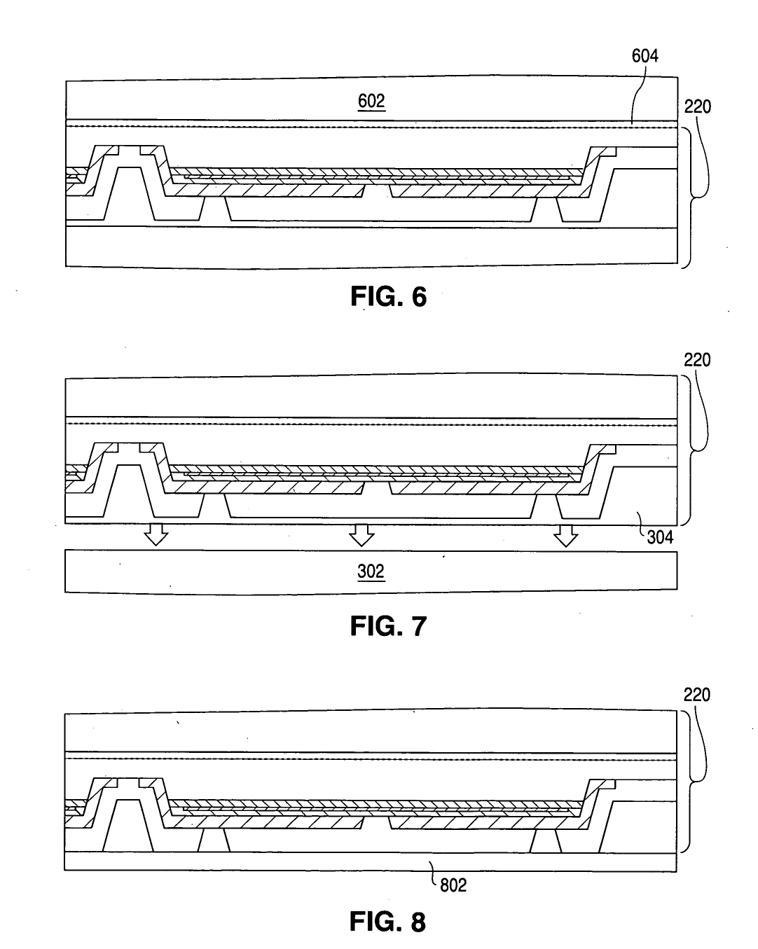

In process 110, a window wafer 602 is bonded to device wafer 220 as shown in FIG. 6. A low index adhesive 604 is first applied over the top of device wafer 220 and window wafer 602 is then bonded to the top of the device wafer. Low index adhesive 604 may have a refractive index equal to or less than 1.5 (e.g., 1.2 to 1.5). Low index adhesive 604 may be applied by a spin-on process.

Window wafer 602 provides mechanical strength to device wafer 220 for subsequent processing. Window wafer 602 may include a wavelength converting structure for modifying the emission spectrum to provide a desired color such as amber for signal lights or multiple colors for a white light emitter. The structure may be a ceramic phosphor, a suitable transparent substrate or carrier such as a sapphire or glass layer, or a filter such as a distributed Bragg reflector. The ceramic phosphor structure is described in detail in U.S. Pat. No. 7,361,938, which is commonly assigned and incorporated herein by reference.

If window wafer 602 is an oxide or other similar material, low index adhesive 604 may be replaced by a silicon dioxide layer applied to the roughened surface of device wafer 220. The silicon dioxide layer may be applied via chemical vapor deposition (CVD), plasma-enhanced CVD (PECVD), or other suitable depositing technique. Window wafer 602 may then be bonded to device wafer 220 using an oxide-oxide wafer bonding technique. Process 110 is followed by process 112.

In process 112, carrier wafer 302 is removed from device wafer 220 as shown in FIG. 7. Carrier wafer 302 may be removed by applying heat, and any remaining temporary adhesive 304 may be removed by a solvent. Process 112 is followed by process 114.

In process 114, device wafer 220 is mounted from the bottom side to a stretch film 802 as shown in FIG. 8. Stretch film 802 may be a blue tape, a white tape, a UV tape, or other suitable materials that allows adhesion to a flexible (expandable) substrate. Process 114 is followed by process 116. Stretch films are commercially available, for example, from the Furukawa Electric Co. and Semiconductor Equipment Corp.

In process 116, LED dies 200 in device wafer 220 are singulated into individual dies. LED dies 200 may be singulated using a laser, a scribe, or a saw. At this point, LED dies 200 are essentially finished devices ready for testing. However, LED dies 200 may have edge emission that degrades color-over-angle uniformity. Process 116 is followed by process 118.

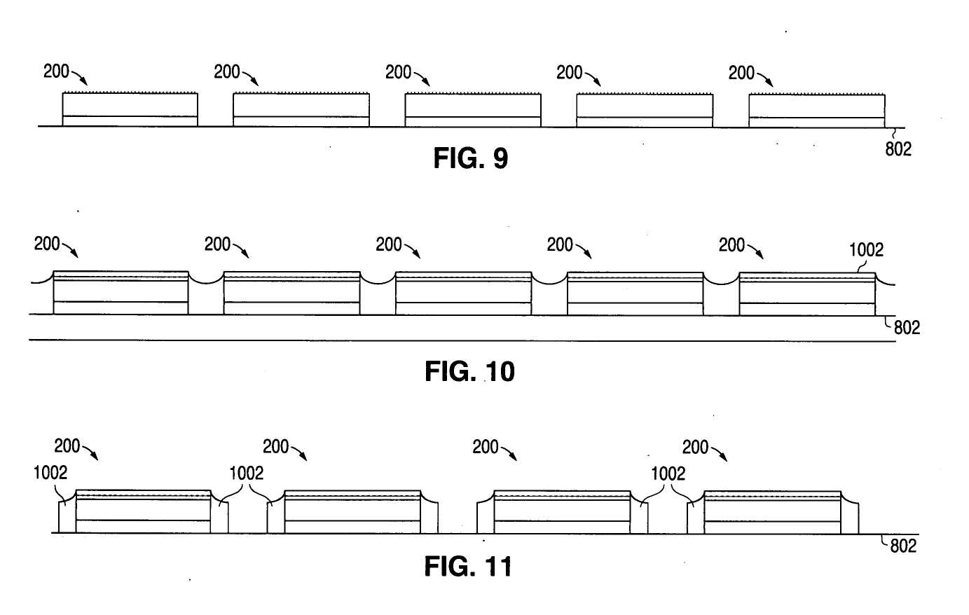

In process 118, stretch film 802 is expanded to laterally separate LED dies 200 and create the spaces between them as shown in FIG. 9. In an alternative embodiment, LED dies 200 are transferred to a rigid carrier wafer from stretch film 802. LED dies 200 may be tape transferred or picked and placed onto the rigid carrier wafer to create the spaces between the LED dies. When LED dies 200 are tape transferred, stretch film 802 is expanded to create the spaces between the LED dies before transferring the LED dies to the rigid carrier wafer. Process 118 is followed by process 120.

In process 120, a reflective coating is applied over the top of LED dies 200 and in the spaces between them. Before the reflective coating is applied, a dielectric may be deposited over the top and/or sides of LED dies 200 to increase reflectivity and/or prevent the reflective coating from shorting out the LED dies. The dielectric has antireflective properties and may be a film of, for example, SiO₂, MgF₂, Si₃N₄ (or SiNₓ), etc.

Depending on the embodiment, the reflective coating may be a polymer or a resin 1002 with reflective particles (hereafter collectively as “reflective coating 1002”) as shown in FIG. 10, or a thin metal film 1402 as shown in FIG. 14. Process 120 to 130 are first described for embodiments using reflective coating 1002 with reference to FIGS. 10 to 13, and then later described for embodiments using thin metal film 1402 with reference to FIGS. 14 to 17.

Referring to FIG. 10, reflective coating 1002 is applied over the top of LED dies 200. Concave menisci in reflective coating 1002 may form in the spaces between LED dies 200. Reflective coating 1002 may be silicone, epoxy, acrylic, etc. The reflective particles in reflective coating 1002 may be TiO₂. Reflective coating 1002 may be applied by a sol-gel or spin-on process. Process 120 is followed by process 122.

In process 122, reflective coating 1002 in the spaces between LED dies 200 (with or without the dielectric coating for increasing reflectivity and/or short prevention) is optionally broken or weakened (e.g., cleaved). Reflective coating 1002 in the spaces between LED dies 200 may be broken or weakened by a laser, a scribe, or a saw. If reflective coating 1002 is brittle, a bar breaking process may be used where LED dies 200 are passed over a rounded bar to break or weaken the reflective coating in the spaces between the LED dies. Reflective coating 1002 may not need to be broken or weakened if concave menisci that weaken reflective coating 1002 are automatically formed in the spaces between LED dies 200. Process 122 is followed by process 124.

In process 124, stretch film 802 is expanded again to further laterally separate LED dies 200 as shown in FIG. 11. This step is not performed in the alternative embodiment of process 118 using a rigid carrier wafer. Process 124 is followed by process 126.

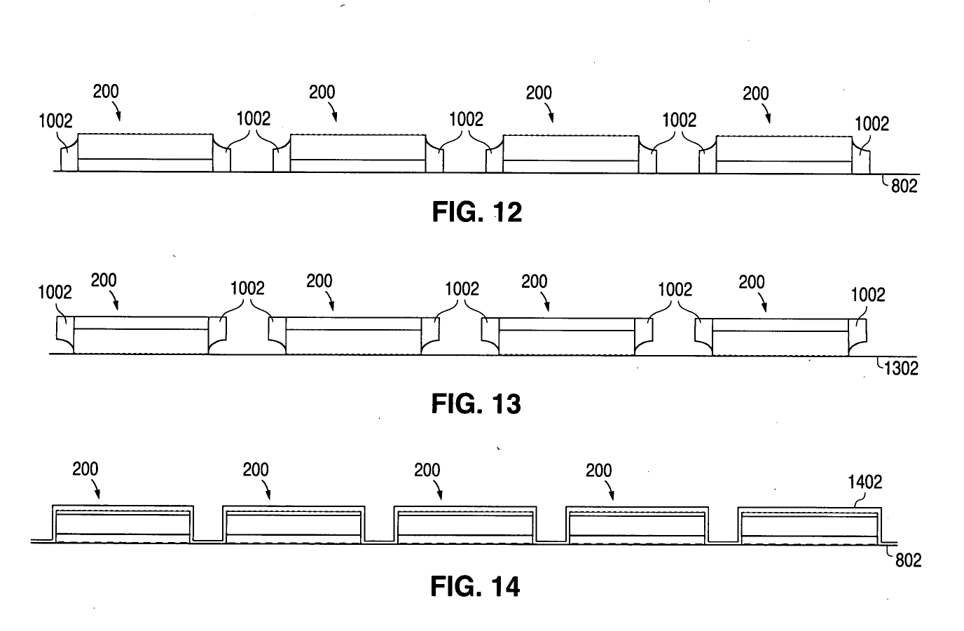

In process 126, portions of reflective coating 1002 on the top of LED dies 200 are removed as shown in FIG. 12. Afterwards only portions of reflective coating 1002 on the lateral sides of LED devices 200 remain. Portions of reflective coating 1002 on the lateral sides of LED dies 200 may control edge emission, improve color-over-angle uniformity, and improve brightness. Portions of reflective coating 1002 on the top of LED dies 200 may be removed by a lift-off process, etching, laser ablation, or abrasive grit blasting. The sacrificial layer for the lift-off process may be deposited in process 120 before reflective coating 1002 is formed over LED dies 200. Process 126 is followed by process 128.

In process 128, LED dies 200 are flipped over and transferred to another stretch film 1302 as shown in FIG. 13. LED dies 200 are mounted from the bottom side to stretch film 1302 and then stretch film 802 is removed so n-type bond pads 216 and p-type bond pads 218 (not shown in FIG. 13) of the LED dies are exposed on the top side for testing. It may be possible to test LED dies 200 without transferring them to a second stretch film 1302 if bond pads 216 and 218 are accessible through the first stretch film 802. Process 128 is followed by process 130.

In process 130, the individual LED dies 200 may be tested while they are affixed on stretch film 1302.

Process 120 to 130 are now described for embodiments using thin metal film 1402 with reference to FIGS. 14 to 17.

Referring to FIG. 14, thin metal film 1402 is formed over the top of LED dies 200 and in the spaces between them. Thin metal film 1402 may be any reflective metal or alloy such as Al, Ag, Cr, Au, Ni, V, Pt, Pd, etc and combination thereof. Thin metal film 1402 may be formed by evaporation or sputtering. Process 120 is followed by process 122.

In process 122, thin metal film 1402 in the spaces between LED dies 200 is optionally broken or weakened (e.g., cleaved). Reflective coating 1402 in the spaces between LED dies 200 may be broken or weakened by a laser, a scribe, or a saw. If reflective coating 1402 is brittle, a bar breaking process may be used where LED dies 200 are passed over a rounded bar to physically break or weaken the reflective coating in the spaces between the LED dies. In the alternative embodiment of process 118 using a rigid carrier wafer, thin metal film 1402 in the spaces between LED dies 200 may be etched. Process 122 is followed by process 124.

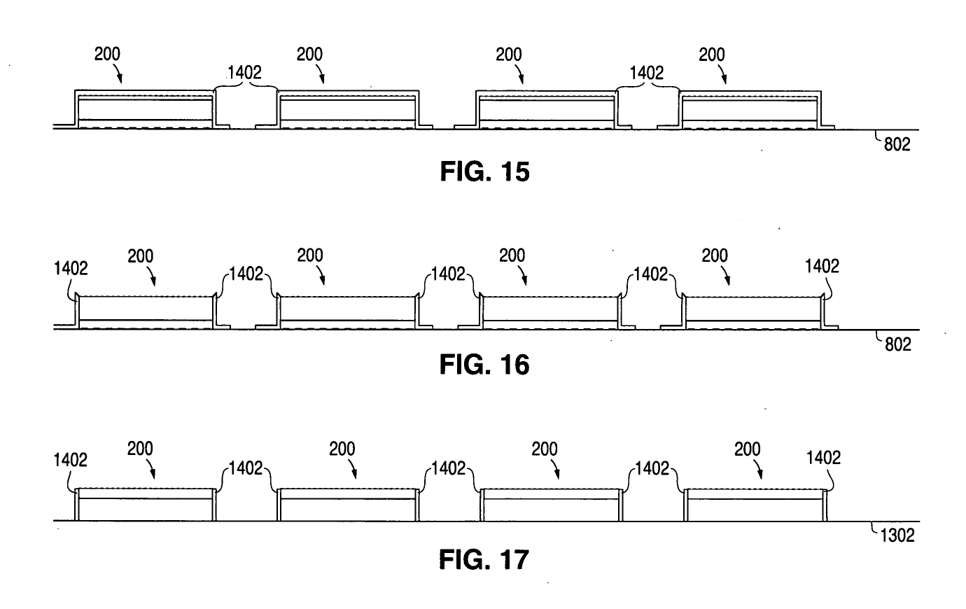

In process 124, stretch film 802 is expanded again to further laterally separate LED dies 200 as shown in FIG. 15. This step is not performed in the alternative embodiment of process 118 using a rigid carrier wafer. Process 124 is followed by process 126.

In process 126, portions of thin metal film 1402 on the top of LED dies 200 are removed as shown in FIG. 16. Afterwards only portions of thin metal film 1402 on the lateral sides of LED devices 200 remain. Thin metal film 1402 on the lateral sides of LED dies 200 may control edge emission, improve color-over-angle uniformity, and improve brightness. Portions of thin metal film 1402 on the top of LED dies 200 may be removed by a lift-off process, etching, laser ablation, or abrasive grit blasting. The sacrificial layer for the lift-off process may be deposited in process 120 before reflective coating 1402 is formed over LED dies 200. In the alternative embodiment of process 118 using a rigid carrier wafer, processes 122 and 126 may be combined in a single etch. Process 126 is followed by process 128.

In process 128, LED dies 200 are flipped over and transferred to another stretch film 1302 as shown in FIG. 17. LED dies 200 are mounted from the bottom side to stretch film 1302 and then stretch film 802 is removed so n-type bond pads 216 and p-type bond pads 218 (not shown in FIG. 17) of the LED dies are exposed on the top side for testing. It may be possible to test LED dies 200 without transferring them to a second stretch film 1302 if bond pads 216 and 218 are accessible through the first stretch film 802. Process 128 is followed by process 130.

In process 130, the individual LED dies 200 may be tested while they are affixed on stretch film 1302. Various other adaptations and combinations of features of the embodiments disclosed are within the scope of the invention. For example, when the reflective coating is a polymeric resin loaded with reflective particles, a very thin layer may be left on the top of LED dies 200 to serve as an optical diffuser or to make the top of the dies appear the same color as the reflective particles (e.g., white). Numerous embodiments are encompassed by the following claims.

What is claimed is:

1. A method for wafer scale fabrication of light emitting diode (LED) structures, comprising:
singulating LED dies in a device wafer;
separating the LED dies to create spaces between the LED dies;
applying a reflective coating in the spaces between the LED dies; and
breaking or separating the reflective coating in the spaces between the LED dies, wherein portions of the reflective coating remain on the lateral sides of the LED dies to control edge emission.

2. The method of claim 1, wherein the reflective coating is a polymer or a resin with reflective particles.

3. The method of claim 2, wherein the reflective coating is silicone, epoxy, or acrylic, and the reflective particles are TiO₂.

4. The method of claim 2, wherein applying the reflective coating over the LED dies and in spaces between the LED dies comprises applying the reflective coating in a sol-gel process or a spin-on process.

5. The method of claim 1, wherein the reflective coating is a thin metal film.

6. The method of claim 5, wherein the reflective coating is Al, Ag, Cr, Au, Ni, V, Pt, Pd, or a combination thereof.

7. The method of claim 5, wherein applying the reflective coating over the LED dies and in the spaces between the LED dies comprises applying the reflective coating by evaporation or sputtering.

8. The method of claim 1, further comprising:
prior to singulating the LED dies, mounting the LED dies in the device wafer to a stretch film;
wherein separating the LED dies comprises transferring the LED dies from the stretch film to a carrier wafer to create the spaces between the LED dies.

9. The method of claim 1, further comprising:
prior to singulating the LED dies, mounting the LED dies in the device wafer to a stretch film;
wherein separating the LED dies comprises expanding the stretch film to laterally separate the LED dies prior to applying the reflective coating over the LED dies and in the spaces between the LED dies.

10. The method of claim 9, wherein the breaking or separating the reflective coating in the spaces between the LED dies comprises:
weakening or breaking the reflective coating in the spaces between the LED dies; and
again expanding the stretch film to further separate the LED dies.

11. The method of claim 9, further comprising:
removing any reflective coating from the top of the LED dies.

12. The method of claim 11, wherein removing the reflective coating from the top of the LED dies comprises a lift-off process, etching, laser ablation, or grit-blasting.

13. The method of claim 11, further comprising:
mounting the LED dies to another stretch film from the other side of the LED dies; and
removing the stretch film from the LED dies.

14. The method of claim 13, further comprising:
testing the LED dies after mounting the LED dies to the other stretch film from the other side of the LED dies.
